(19) United States
(12) Patent Application Publication
(10) Pub. No.: US 2019/0207048 A1
(43) Pub. Date: Jul. 4, 2019

(54) SOLAR ENERGY COLLECTION AND TRANSMISSION DEVICE AND METHODS OF USING THEREOF

(71) Applicant: HANGZHOU LINGYING TECHNOLOGY CO., LTD., Hangzhou (CN)

(72) Inventor: Guohua LI, Hangzhou (CN)

(73) Assignee: HANGZHOU LINGYING TECHNOLOGY CO., LTD., Hangzhou (CN)

(21) Appl. No.: 16/294,901

(22) Filed: Mar. 6, 2019

Related U.S. Application Data
(63) Continuation of application No. PCT/CN2017/101708, filed on Sep. 14, 2017.

(30) Foreign Application Priority Data
Sep. 30, 2016 (CN) 201610871699.8

(51) Int. Cl. H01L 31/054; H01L 31/20; F24S 20/20

(52) U.S. Cl. CPC H01L 31/0547; F24S 20/20; H01L 31/208

(57) ABSTRACT

A solar energy collection and transmission device includes a light-transmitting body, a transmission layer and a plurality of reflectors connected to each other, wherein the transmission layer is provided with a light collection port. Each reflector includes an acquisition transmission plate having a reflective surface defined by an arc. The solar energy collection and transmission device also has a large light wavelength collection range which can be directly utilized or transformed after collection, having a high aggregation degree, small transmission loss, unrestricted shape and wide application range.

### CROSS-REFERENCE TO RELATED APPLICATIONS

The present application claims priority to PCT/CN2017/101708 filed on Sep. 14, 2017, which in turn claims priority to Chinese Patent Application No. CN 201610871699.8 filed on Sep. 30, 2016. The disclosures of these applications are hereby incorporated by reference in its entirety.

### COPYRIGHT STATEMENT

A portion of the disclosure of this patent application document contains material that is subject to copyright protection including the drawings. The copyright owner has no objection to the facsimile reproduction by anyone of the patent document or the patent disclosure as it appears in the Patent and Trademark Office file or records, but otherwise reserves all copyright rights whatsoever.

### BACKGROUND

The development of solar energy utilization technology has enabled solar power generation technology and solar lighting technology to gradually enter people's field of vision. The difference in day and night, low solar density, difficulty in collecting, etc., resulting in high solar energy utilization costs, is the main factor hindering the widespread use of the sun.

### SUMMARY

The present disclosure relates to a solar energy collecting and conveying device and a principle thereof, which have large collection range, can be directly utilized or transformed after collection, have high aggregation degree, small transmission loss, unrestricted shape and wide application range. It belongs to solar energy collection and transmission technology and application fields.

Various embodiments of the present disclosure provide a solar energy collection and transmission device and a principle thereof, which have large collection range, can be directly utilized or transformed after collection, have high aggregation degree, small transmission loss, unrestricted shape and wide application range. The disclosure solves the problems of collection of solar energy utilization technologies existing in the prior art, and utilization of low efficiency and the like.

In an aspect, a solar energy collecting and conveying device is provided, including a light transmitting body, a conveying layer and a plurality of reflecting bodies, wherein the reflecting body is fixed by the light transmitting body, and a light collecting port is arranged in the conveying layer; the reflecting body comprises an arc A₀A_{X}, line A₀B, line BC enclosed transmission board; A₀ end of arc A₀ A_{X} is connected with A₀ end of line A₀B and C end of line BC.

The central angle corresponding to the arc A₀-A_{X} is 0-90°, and the angle between the straight line A₀B and the straight-line B-C is 0-180°.

In some embodiments, the arc A₀-A_{X} corresponds to a central angle of 20 to 750°.

The reflector and the light-transmitting body may be an integrally formed structure, and the inside of the reflector may be provided with a filling substance. The inside of the reflector can be filled with any substance, and when the reflector and the light-transmitting body are produced, the material of the reflector can be reduced, and other inexpensive materials can be used instead of the material, thereby reducing the cost.

The interior of the reflector may be provided with a filling substance, which is a solid, a gas or a vacuum. When the light transmitting body is a solid, the reflector is fixed on the light transmitting body; when the light transmitting body is a liquid, a gas or a vacuum, the reflecting body is fixed by a separate fixing device.

The light incident interface of the light-transmitting body may be disposed in an inclined manner with an inclination angle of 0-90°. The light incident on the obliquely disposed light-transmitting body can change the oblique light into vertical light.

A first transmissive film may be disposed at a top end of the transparent body, a second transmissive film is disposed on an upper end surface of the transmissive layer; a first reflective film is coated around the reflective body, and an upper end surface and a bottom end surface of the upper end surface of the transport layer Provided with a second reflective film; the arc A₀ A_{X} film extends into the upper end surface of the transport layer and is provided with a second reflective film, and the lower end surface is provided with a third transmissive film, which avoids back and forth reflection of light in the transport layer, resulting in loss The rate is improved.

The arc A₀ A_{X} of all the reflectors is sequentially arranged in one direction on the light transmitting body.

The plurality of reflectors A₀ A_{X} are sequentially arranged in one direction on the light-transmitting body to form a first collection group, and the plurality of reflectors A₀ A_{X} are sequentially arranged in one direction on the light-transmitting body to form a second collection group; the first collection group wherein the orientation of the middle arc A₀ A_{X} is opposite to the orientation of the arc A₀ A_{X} in the second collection group.

In another aspect, a method of a solar energy collection involving a transmission device is provided, the method including the following steps.

1) Construct a light vertical incidence model, define the light entering the light beam into the interface, and then vertically enter the circle O, A is the point on the circle O, OA is the horizontal line, and the vertical incident light a and the inner surface of the circle O The intersection point is A₀, <AO A₀=α, then: the intersection point A₁ of the primary reflection line A₀ A₁ and the arc, <AO A₁=3α, the intersection point A₂ of the secondary reflection line A₁ A₂ and the arc, <AO A₂=5α;

It can be concluded that: <AOAn=(2n+1)α, where n is the number of times the light is reflected on the inner surface of the arc, and its value is 1, 2, 3 . . . n;

2) Define the vertical light a+ into the circle O, the distance between the intersection of the incident light a+ and OA and the center of the circle O is X, the primary reflected light of the incident light a and a+ intersects at point B, and the arc AB distance in the area OBA The distance of the O arc decreases as X increases;

It can be concluded that in the coordinate system with the center O as the origin, the point B uses the X expression: B=−2X²(1−X²)^{1/2};

It can be concluded that the reflected light passes through the points in the area OBA and the circle OA region;

3) The intersection of the incident light a+ and OA is defined as Xx, and the primary reflected light of the incident light perpendicular to the Xx and X0 intervals is surrounded by A₀ A_{X} CB; the value of x in Xx is 1, 2, 3 . . . x.

At least some embodiments of the disclosure can have one or more of the following advantages.

For example, a solar energy collection and transmission device and a method of collection can have a large range of collection, can directly utilize or transform a collection point, or can be utilized or converted after long-distance transmission, can collect diffused light, can be applied to solar illumination, or can be light. Heat utilization can also generate electricity from solar cells. High degree of aggregation, small transmission loss, unrestricted shape, wide application range, can be used for solar energy utilization, can also be used for shading, outside the structure, wall and so on. The principle of a solar energy collection and transmission device is directed to a solar energy collection and transmission device, which solves the problem of the size setting of the reflector. The material of the reflector is cheaper than the material of the light-transmitting body, which can reduce the cost of the solar energy collection and transmission device and increase the economy.

### BRIEF DESCRIPTION OF THE DRAWINGS

In order to more clearly illustrate the embodiments of the present disclosure or the technical solutions in the prior art, the drawings used in the embodiments or the description of the prior art will be briefly described below. Obviously, the drawings in the following description are only It is a certain embodiment of the present disclosure, and other drawings can be obtained from those skilled in the art without any inventive labor.

FIG. 1 illustrates a side cross-sectional view of a schematic structure of a solar energy collection and transmission device and various principles thereof in accordance with various aspects of the present disclosure;

FIG. 2 illustrates a schematic structural view of a solar energy collecting and transmitting device and a reflective body thereof according to the present disclosure;

FIG. 3 illustrates a schematic diagram of a solar energy collection and transmission device and a principle thereof according to the present disclosure;

FIG. 4 illustrates a schematic diagram of a solar energy collection and transmission device and a principle thereof according to the present disclosure;

FIG. 5 illustrates a schematic diagram of a solar energy collection and transmission device and its principle according to the present disclosure;

FIG. 6 illustrates a schematic diagram showing a unidirectional structure of a solar energy collecting and transmitting device and a principle thereof according to the present disclosure;

FIG. 7 illustrates a schematic diagram showing a multi-directional structure of a solar energy collecting and transmitting device and a principle thereof according to the present disclosure;

FIG. 8 illustrates a schematic view showing the structure of a surface auxiliary film of a light-transmitting body according to a solar energy collecting and transmitting device and a principle thereof;

FIG. 9 illustrates a schematic view showing a tilting structure of a surface of a light-transmitting body according to a solar energy collecting and transmitting device and a principle thereof;

FIG. 10 illustrates a unidirectional ray refraction diagram of a solar energy collection and transmission device and a principle thereof according to the present disclosure;

FIG. 11 illustrates a multi-directional light refraction diagram of a solar energy collection and transmission device and a principle thereof according to the present disclosure;

FIG. 12 illustrates a light refraction diagram of a surface coating of a light-transmitting body of a solar energy collecting and transmitting device and a principle thereof according to the present disclosure; and

FIG. 13 illustrates a perspective view of a tilted light refracting surface of a light-transmitting body of a solar energy collecting and transmitting device and a principle thereof according to the present disclosure.

### DETAILED DESCRIPTION

The specific embodiments of the present disclosure are further described below in conjunction with the accompanying drawings. It is to be noted that the description of the embodiments is intended to aid the understanding of the disclosure, but is not intended to limit the disclosure. Further, the technical features involved in the various embodiments of the present disclosure described below may be combined with each other as long as they do not constitute a conflict with each other.

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or other structure is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “horizontal” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The inventor of the present disclosure has recognized that, at present, the solar energy utilization mainly includes solar illumination, and the optical fiber is collected. The diameter of the collected light is small, and it is not suitable for large-area collection; the lens is collected, the volume is large, and the shape is limited, the collection area is restricted, the diffused light cannot be used, and the transmission is difficult; an array requires accurate sun tracking and positioning device, complicated mechanical structure, high cost, moving parts, repair problems, etc., cannot use diffused light.

Solar heat utilization, vacuum tube energy density is not high, temperature cannot be further improved, only suitable for small-scale heating; lens collection, bulky, limited by shape, collection area is restricted, transmission is difficult, cannot use diffused light; solar reflective array Need precise sun tracking and positioning device, complicated mechanical structure, high cost, moving parts, repair problems, etc., cannot use diffused light.

The efficiency of solar power generation and solar cells is low. The operating efficiency of monocrystalline silicon cells is less than 30%, the working efficiency of commercial use is not even 20%, the working range is limited by frequency bands, other parts are converted into heat energy, and cooling is caused. Problems, aging problems, high cost issues, etc.

As such, in order to solve the problem of difficulty in collecting solar energy utilization technology in the prior art, and utilizing low efficiency, it is urgent to invent a large collection range, which can be directly utilized or converted after collection, with high aggregation degree and small transmission loss. The shape is not limited, and a wide range of solar energy collection and transmission devices and their principles are applicable.

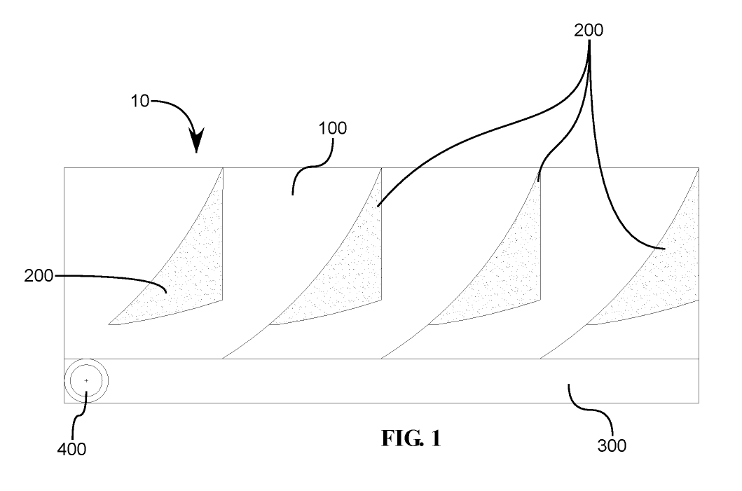

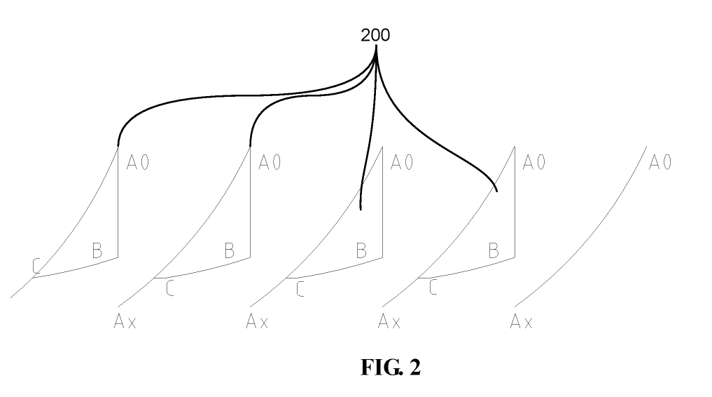

Referring to FIG. 1, which illustrates a schematic diagram of an exemplary structure of a solar energy collecting and transmitting device 10 and a principle thereof. Wherein FIG. 2 particularly illustrates a structural diagram of an array of reflecting bodies provided therein. In particular, together these elements form a solar energy collecting and transmitting device 10 which is formed of a light-transmitting body 100 containing one or more reflectors 200 embedded therein. The light-transmitting body can receive light from a first surface which transmits through the light-transmitting body hitting the one or more reflectors 200. The reflectors then redirect the light through a second surface of the light transmitting body at a particularly desired angle. A transport layer 300 is provided on the second surface of the light-transmitting body 100 such that the light is directed toward or otherwise intensified at a light collection port 400 which is embedded within the transport layer 300.

Each of the reflectors 200 can have a particular reflective surface 204 being configured to receive the light transmitted through the light-transmitting body 100. In particular this reflective surface 204 can be a concave surface being described as an arc extending from the points A₀-A_{X}. Each reflector 200 can also have a rear surface 208 which can be provided as a straight line extending from the points A₀-B. Each reflector can then also include a bottom surface 212, which can be referred to as the acquisition transmission board and which is illustrated by the straight line from points B-C.

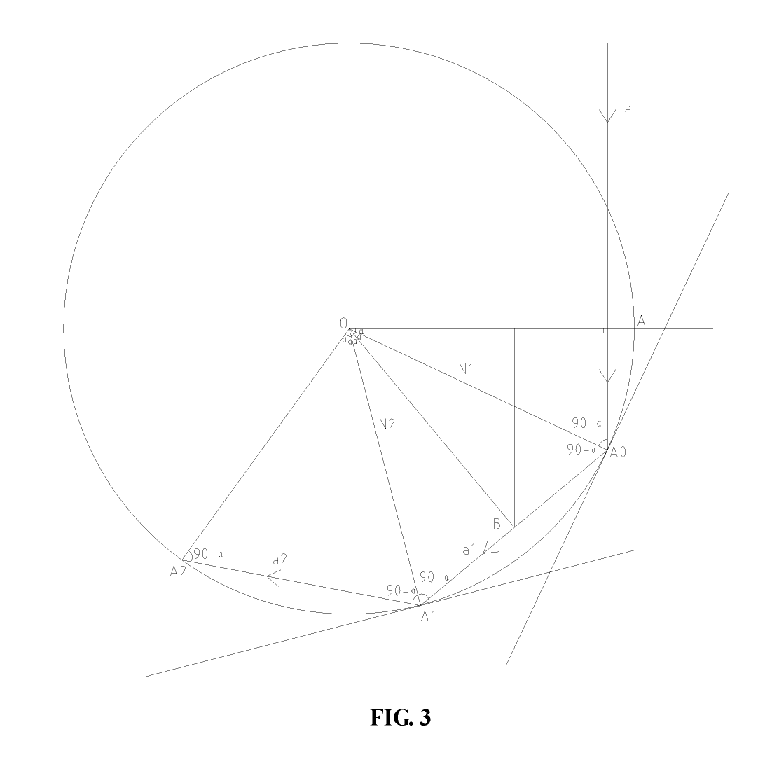

As illustrated here, and particularly in FIG. 3, the central angle corresponding to the arc or about the focal point from A₀-A_{X} is 0-90°, and the angle between the straight line A₀-B and the straight-line B-C is 0-180°. In a preferred embodiment, the arc A₀-A_{X} corresponds to a central angle of 20 to 750°.

The reflector 200 and the light-transmitting body 100 may be an integrally formed structure, and the inside of the reflector 200 may be provided with a filling substance. The inside of the reflector 200 can be filled with any substance so long as the surface 204 is provided as a reflective surface. When the reflector 200 and the light-transmitting body 100 are produced, the material of the reflector 200 can be reduced, and other inexpensive filler materials can be used instead of the particular material forming the reflective surface 204, thereby reducing the cost.

As discussed herein, the filling material of the reflector can be provided as a solid substance, a liquid, a gas, or it can also be a void or a vacuum. Similarly the light transmitting body 100 can be provided as a solid translucent substance, a liquid, a gas, or a vacuum with structure about a perimeter edge providing a seal or membrane barrier.

In particular, when the light-transmitting body 100 is provided as a solid substance, the reflector 200 can be fixed to the light-transmitting body 100 by being embedded therein. Alternatively, when the light-transmitting body 100 is provided as a liquid, a gas or a vacuum, the reflector 2 is fixed by a separate fixing device or support structure which maintains the relative position of each reflector 200 within the light-transmitting body 100. Such supports can be provided as brackets, filaments, wires, etc. which can connect to an exterior seal or support structure of the light-transmitting body 100 so as to properly maintain relative position therein.

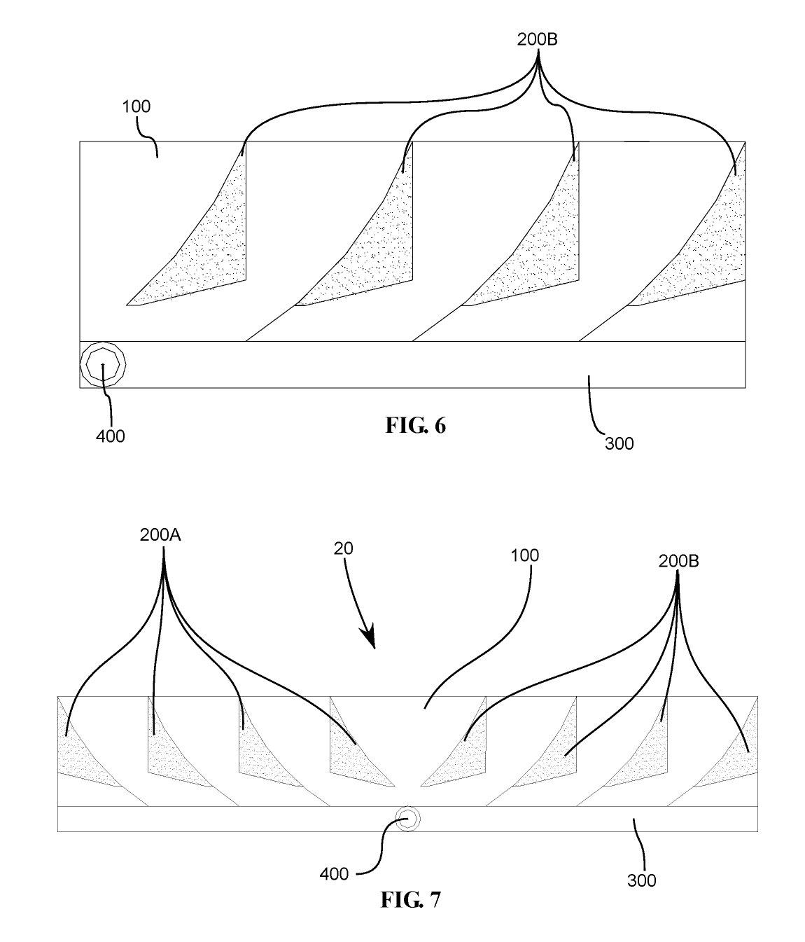

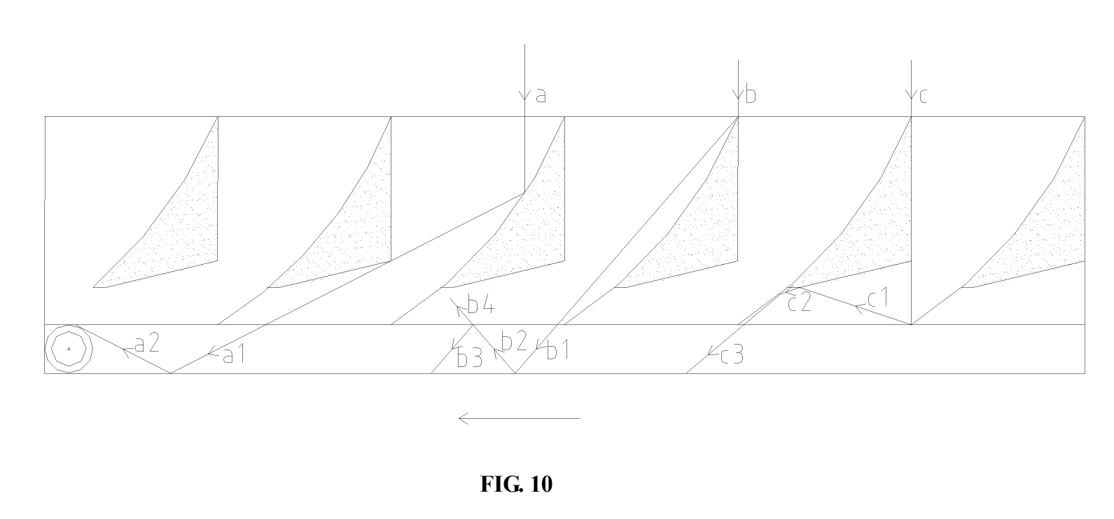

Referring to FIG. 6 and FIG. 10, a solar energy collection and transmission device is illustrated in which each of the reflectors are configured so as to reflect light in a common direction. In other words, each of the arcs A₀-A_{X} of all the reflectors 200 are sequentially arranged in one direction within the light-transmitting body 100.

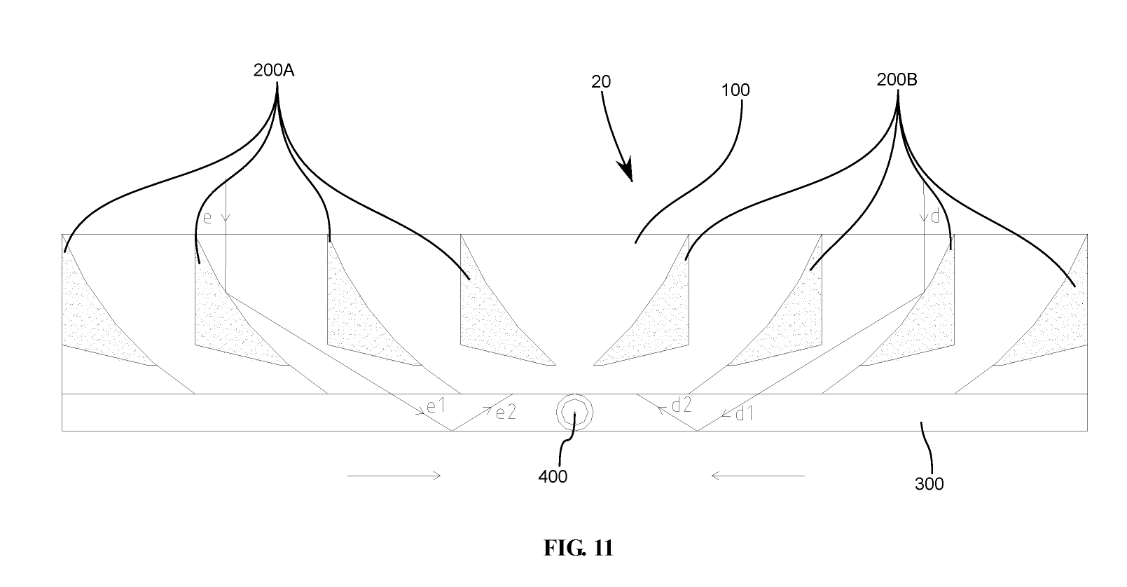

In other embodiments, reference is made to the two-way structure diagram of the solar energy collecting and transmitting device 20 is illustrated with various principles thereof as shown in FIG. 7 and FIG. 11 wherein the reflectors provided within the light-transmitting-body 100 can be arranged such that an associated light refraction pattern is achieved which allows for light reflection in more than one direction from opposingly arranged reflectors.

In this embodiment the arc A₀-A_{X} of a first reflectors 200A are arranged so as to reflect light in a first direction while at least a second reflector 200B is arranged so as to reflect light in a second direction. It will be appreciated that each of the reflectors can also be arranged in an array of first reflectors configured to reflect light in a first direction and an array of second reflectors configured to reflect light in a second direction.

In this manner a set or plurality of first reflectors 200A can be sequentially arranged within the light-transmitting body 100 so as to form a first collection group 250A. Similarly the arcs A₀-A_{X} of the plurality of second reflectors 200B can then be similarly sequentially arranged in an alternative direction within the light-transmitting body 100 so as to form a second collection group 250B. In this embodiment the orientation of the associated arcs A₀-A_{X} in the first collection group can then be arranged so as to be opposite to the orientation of the associated arcs A₀-A_{X} in the second collection group. In this manner, the arrangement of the second collection group and the first collection group can then allow increased light collection efficiency from a common light source.

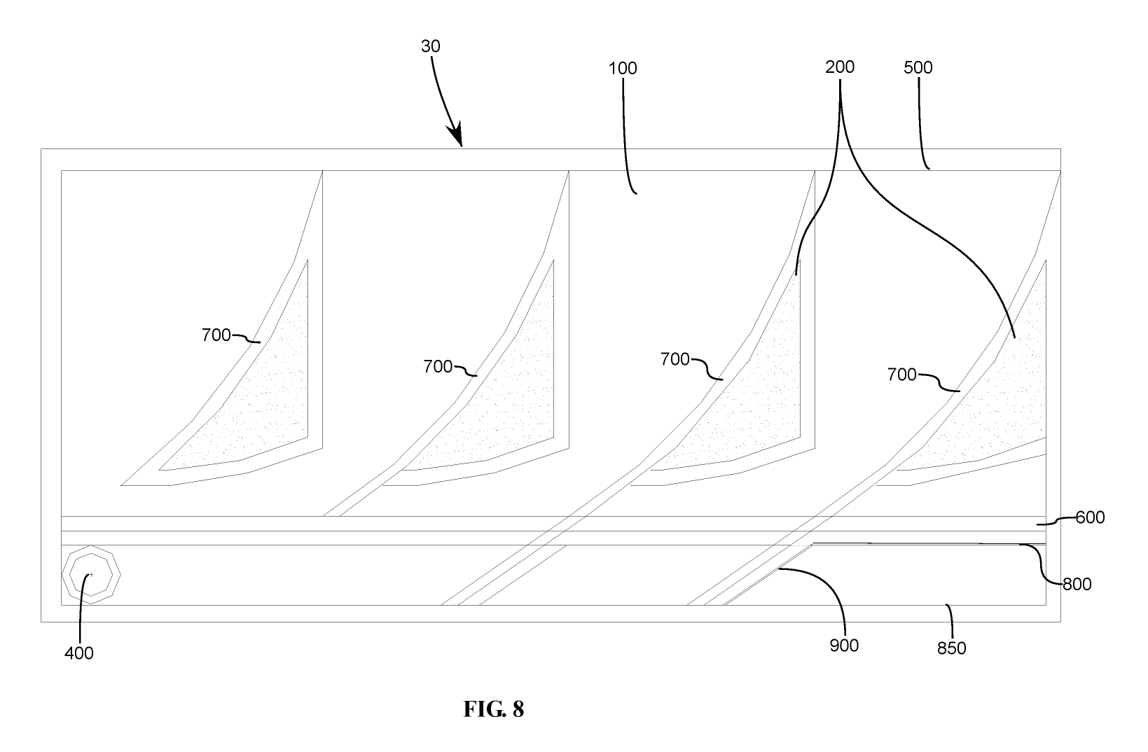

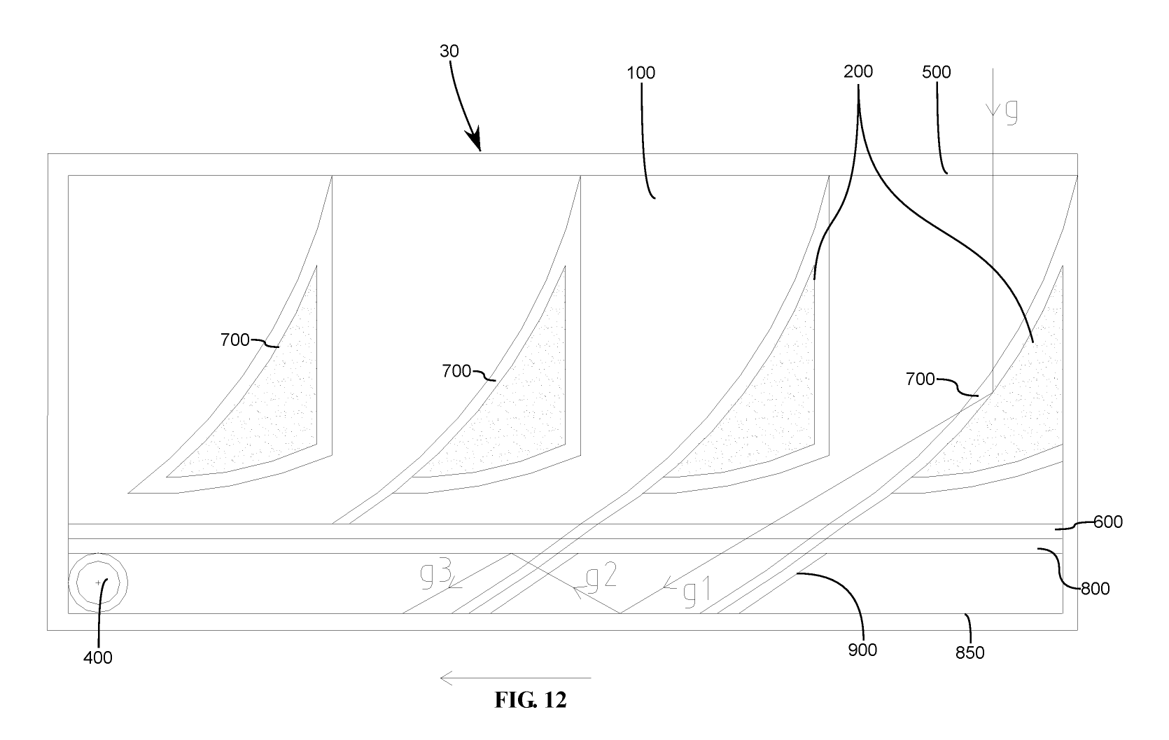

In other embodiments, and as shown in FIG. 8 and FIG. 12, a side-cross sectional schematic diagram of a solar energy collecting and transmitting device 30 is illustrated having a surface structure of a light-transmitting body and a principle thereof and a light-refraction diagram of a surface-reflecting body of a light-transmitting body. In this embodiment, the light-transmitting body 100 is provided with a first transmissive film 500 which is disposed at a top end of the light-transmitting body 100 or on a top surface as illustrated in these figures. Also provided in this embodiment is a second transmissive film 600 which is disposed on an upper surface of the transport layer 300 between the light-transmitting body 100 and the transmitting layer 300. In this embodiment, each of the reflective bodies 200 are surrounded by a first reflective film 700. In some additional embodiments a third reflective film 850 can also be provided to a bottom surface of the transport layer 300 such that light entering the transport layer can then have difficulty escaping therefrom.

In some additional embodiments the transport layer 300 can also be provided with a second reflective film 800 which can be provided between portions of the second transmissive film 600 and the top surface of the transport layer 300. In some such embodiments, the first reflective film 700 provided the upper surface of the arc A₀-A_{X} film can be configured to extend into the transport layer 300, and is some alternative such embodiments, the second reflective film 800 can also extend into the transport layer 300, wherein a back side of the reflective film 800 can also be provided with a third transmissive film 900, effectively turning the second reflective film 800 into a one-way reflective surface within the transport layer 300. In this manner, light transmitted from a back or convex surface can transfer through the film, but wherein light will be reflected from a front or concave side thereof. In this manner, as illustrated herein light traveling from right to left within the transport layer 300 will be funneled toward the collection port 400. The arrangement of the first transmissive film 500 and the second transmission film 600 can thus reduce the transmission loss rate when light enters the light-transmitting body 100, and the arrangement of the first reflection film 700 and the second reflection film 800 avoids back-reflection of light rays in the within the transmissive layer 300, which would otherwise result in an increased light loss rate.

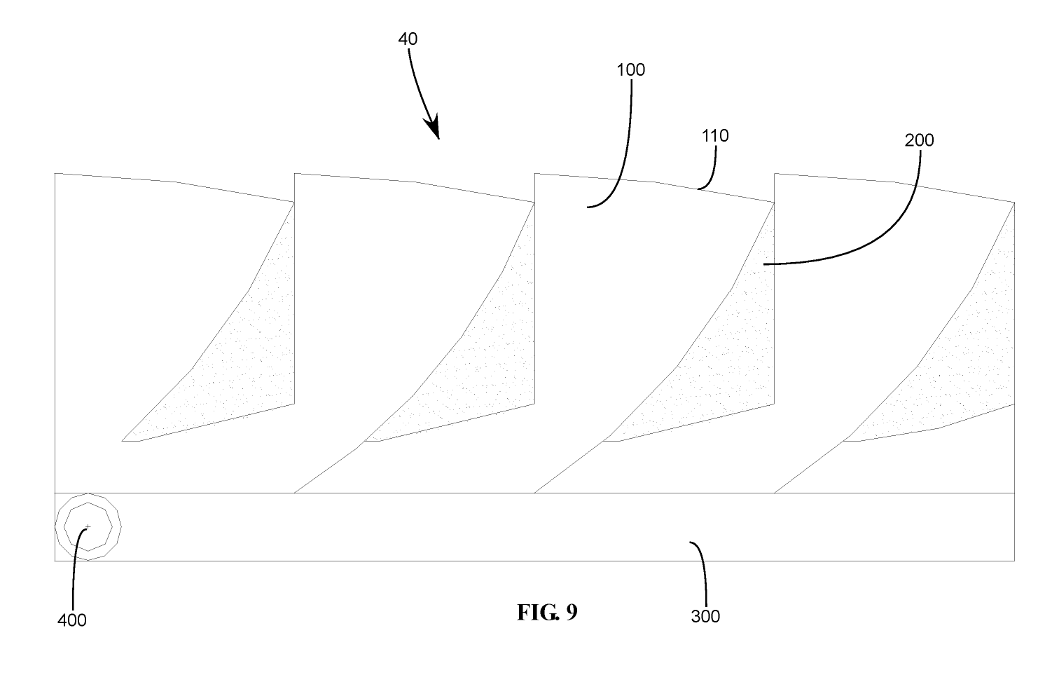

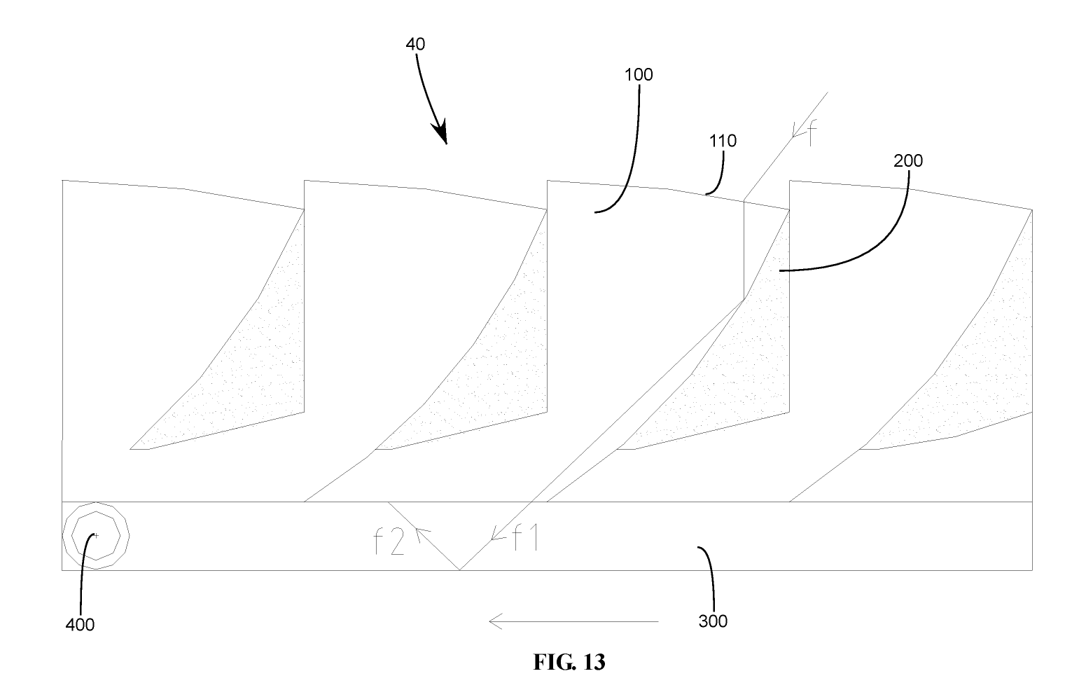

In other embodiments, reference is made to another optional solar energy collecting and transmitting device 40, as shown in FIG. 9 and FIG. 13, wherein illustrated is yet another schematic diagram. In this exemplary embodiment, portions of the light-transmitting body 100 can be provided with an inclined surface structure 110. In this embodiment, the inclined surface structure 110 can be provided with an oblique light refracting pattern corresponding with an associated light input angle so as to correct the light input angle so as to direct the light in a desired angle toward each of the reflectors 200 provided within the light-transmitting body 100. As illustrated herein, the light injection interface of each of the reflectors 200 can be set to be inclined, wherein the inclination angle can then be between 0-90°. The light incident on the obliquely disposed surface 110 of the light-transmitting body 100 can thus change the oblique light into vertical light.

As contemplated here, the inclined surface structure 110 can have a flat inclined surface, a graduated curved surface, or a faceted surface as illustrated here, such that the inclined surface causes a normalization of the light entering so as to hit each of the reflectors 200 with desired characteristics.

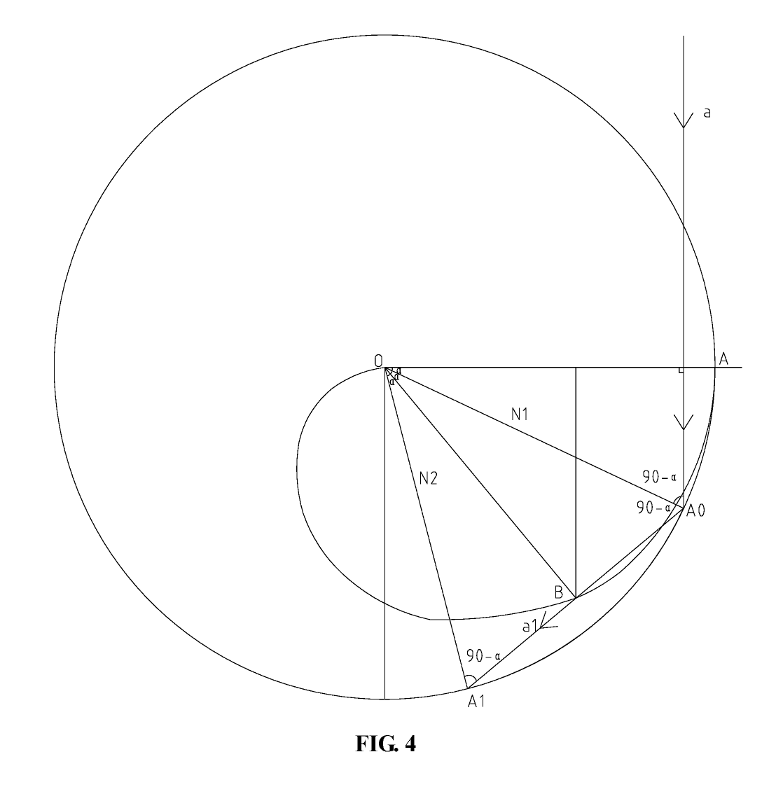

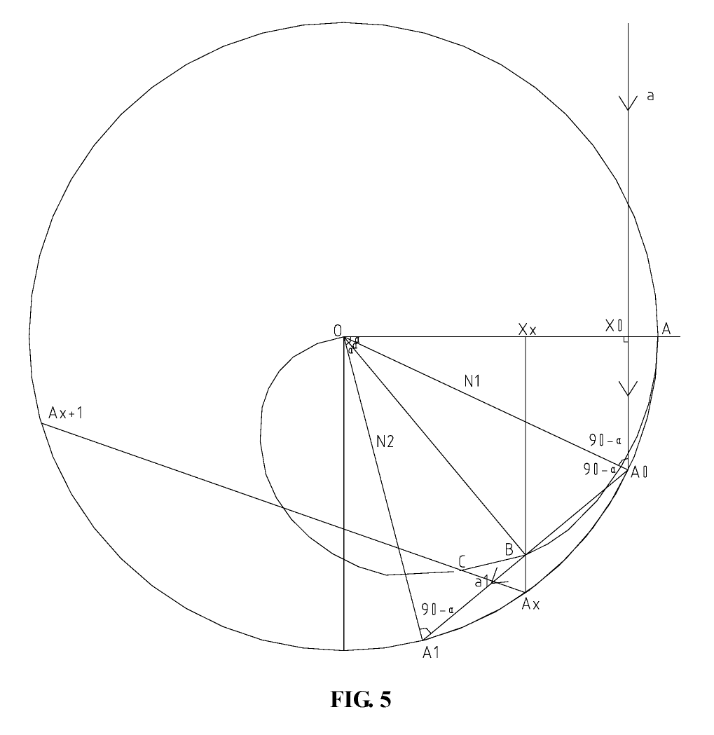

Referring to FIG. 3, FIG. 4 and FIG. 5, a schematic diagram of a solar energy collection and transmission device and a method of using thereof. A method of designing and utilizing a solar energy collection and transmission device can thus be illustrated wherein the method can include the following steps.

1) Construct a light vertical incidence model; define the light entering the light-transmitting body 100 into the interface, and then vertically enter the circle O-A is the point on the circle O, O-A is the horizontal line, and the vertical incident light A and the circle O The surface intersection point is A₀, <AOA₀=α, then: the intersection point A₁ of the primary reflection line A₀A₁ and the arc, <AOA₁=3α, the intersection point A₂ of the secondary reflection line A₁A₂ and the arc, <AOA₂=5α;

It can be concluded that: <AOAn=(2n+1)α, where n is the number of times the light is reflected on the inner or concave surface of the arc, and its value is 1, 2, 3 . . . n;

3) Define the vertical light a+ into the circle O, the distance between the intersection of the incident light a+ and O-A and the center of the circle O is X, the primary reflected light of the incident light a and a+ intersects at point B, and the arc A-B distance in the area O-B-A The distance of the O arc decreases as X increases;

It can be concluded that in the coordinate system with the center O as the origin, the point B uses the X expression: B=−2X²(1−X²)^{1/2};

It can be concluded that the reflected light passes through the points in the area OBA and the circle OA region;

3) The intersection of the incident light a+ and OA is defined as Xx, and the primary reflected light of the incident light perpendicular to the Xx and X0 intervals is surrounded by A₀-A_{X}-C-B; the value of x in Xx is 1, 2, 3 . . . x.

The inventive method then relates to a solar energy collection and transmission device and a principle collection range thereof, which can directly utilize or transform a collection point 400, or can be utilized or converted after long-distance transmission, can collect diffused light, can be applied to solar illumination, or can be light. These principles can then be utilized for purposes of heat utilization which can then also be used so as to generate electricity from solar cells. High degree of aggregation, low transmission loss, unrestricted shape, wide application range, can be obtained for purposes of solar energy utilization, and can also be used for visors, structural external surfaces, walls and so on.

The embodiments of the present disclosure have been described in detail above with reference to the drawings, but the disclosure is not limited to the described embodiments. It will be apparent to those skilled in the art that various changes, modifications, substitutions and variations of the embodiments are possible without departing from the spirit and scope of the disclosure.

Specific examples are used herein to describe the principles and implementations of some embodiments. The description is only used to help understanding some of the possible methods and concepts. Meanwhile, those of ordinary skill in the art may change the specific implementation manners and the application scope according to the concepts of the present disclosure. The contents of this specification therefore should not be construed as limiting the disclosure.

In the descriptions, with respect to device(s), group(s), structure(s), system(s), etc. in some occurrences singular forms are used, and in some other occurrences plural forms are used in the descriptions of various embodiments. It should however be noted that mention to the single or plural forms are not limiting but rather are for illustrative purposes. Unless it is expressly stated that a single device, group, or system etc. is employed, or it is expressly stated that a plurality of devices, groups, or systems etc. are employed, the device(s), group(s), structure(s), system(s), etc. can be singular, or plural.

Based on various embodiments of the present disclosure, the disclosed apparatuses, devices, and methods may be implemented in other manners.

Dividing the terminal or device into different “portions,” “units,” “components,” etc., merely reflect various logical functions according to some embodiments, and actual implementations can have other divisions of “portions,” “units,” or “components” realizing similar functions as described above, or without divisions. For example, multiple portions, units, components may be combined or can be integrated into another system. In addition, some features can be omitted.

Those of ordinary skill in the art will appreciate that the modules, circuits, units, portions, or components in the devices provided by various embodiments described above can be configured in the one or more devices described above. They can also be located in one or multiple devices that is (are) different from the example embodiments described above or illustrated in the accompanying drawings. For example, the modules, circuits, units, portions, or components in various embodiments described above can be integrated into one module or divided into several sub-modules.

The order in which various embodiments described above are only for the purpose of illustration, and do not represent preference of embodiments.

Although specific embodiments have been described above in detail, the description is merely for purposes of illustration. It should be appreciated, therefore, that many aspects described above are not intended as required or essential elements unless explicitly stated otherwise.

Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation to encompass such modifications and equivalent structures.

1. A solar energy collecting and transmitting device, the device comprising:
a light-transmitting body,
a transport layer provided about a bottom surface of the light-transmitting body;
a plurality of reflective bodies provided within the light-transmitting body; and
a light-transporting port disposed with in the transport layer; and
wherein each reflective body includes a concave surface being defined as an arc A₀-A_{X}.

2. The solar energy collecting and transmitting device according to claim 1, wherein each of the reflective bodies are defined as having a constrained area between the arc A₀-A_{X}, a first line A₀-B about a back surface and a bottom surface being defined as a second line B-C, wherein an end of the second line B-C, is provided along the arc A₀-A_{X}.

3. The solar energy collecting and transmitting device according to claim 2, wherein the arc A₀-A_{X} corresponds to a central angle of 0 to 90°, and the angle between the first line A₀-B and the second line B-C is between 0-180°.

4. A solar energy collection and transmission device according to claim 3, wherein the arc A₀-A_{X} corresponds to a central angle of 20 to 75 degrees.

5. The solar energy collection and transmission device according to claim 1, wherein each of the reflective bodies and the light-transmitting body are integrally formed, and the interior of the reflector may be provided with a filling material, and the filling The substance is a solid, a gas or a vacuum, and the light transmitting body may be a solid, a liquid, a gas or a vacuum.

6. The solar energy collection and transmission device according to claim 1, wherein the light-transmitting body is provided being solid, and each of the reflecting bodies are fixed within the light transmitting body.

7. The solar energy collection and transmission device according to claim 1, wherein the light-transmitting body is filled with a translucent liquid or gas, and wherein each reflective body is suspended within the light-transmitting body.

8. The solar energy collection and transmission device according to claim 1, wherein the light incident interface of the light transmitting body is set to be inclined having a tilt angle between 0-90°.

9. The solar energy collection and transmission device according to claim 1, further comprising:
a first transmissive film provided on an upper surface of the light-transmitting body;
a second transmissive film provided on an upper surface of the transport layer;
a first reflective film surrounding each of the reflective bodies;
a second reflective film provided on a top surface of the transport layer and between the second transmissive film and an upper surface of the transport layer.

10. The solar energy collection and transmission device according to claim 10, wherein the first reflective film extends into the transport layer along the arc A₀-A_{X}.

11. The solar energy collection and transmission device according to claim 10, further comprising a third transmissive film on a rear convex surface of a portion of the first reflective film embedded within the transport layer.

12. The solar energy collection and transmission device according to claim 10, further comprising a third reflective film provided on a bottom surface of the transport layer.

13. The solar energy collection and transmission device according to claim 1, wherein each of the reflectors have an arc A₀-A_{X} arranged in sequence facing a common direction within the light transmitting body.

14. The solar energy collection and transmission device according to claim 1, wherein a first collection group having a plurality of reflectors are sequentially arranged facing a first direction and wherein a second collection group having a plurality of reflectors are sequentially arranged facing a second direction, the second direction being opposite the first direction.

15. The solar energy collection and transmission device according to claim 2; wherein light (a) enters into the light-transmitting body incidentally so as to enter a circle O, wherein a point A is defined as a point on the circle O where the light a enters the light-transmitting body, wherein a line O-A is a normal horizontal line, wherein the light (a) and the circle O intersect on a reflective surface of each of the reflective bodies at a point A₀, wherein the angle between the line A-O and the point A₀ is defined as α, wherein the intersection between a point A₁ is defined by a second reflection point and with the primary reflection line A₀-A₁ has an angle being 3 times that of α, and wherein the intersection of a point A₂ being defined as a third reflection point and wherein the angle of a secondary reflection line A₁-A₂ and the arc has an angle <AO-A₂ being equal to 5 times α.

16. The solar energy collection and transmission device according to claim 15, wherein the reflective bodies are configured to reflect incoming light a plurality of times, and wherein an angle between the line A-O and an ultimate reflection point An can be described by the equation <A-O-An=(2n+1)α, wherein n is the number of times the light is reflected on the inner surface of the arc.

17. A solar energy collection and transmission system, the system comprising:
a light transmitting body having a first surface configured for receiving light for collection and a second surface opposite the first surface for emitting collected light therefrom;
a plurality of reflectors suspended within the light transmitting body, wherein each reflector has a reflective surface, wherein the reflective surface is a concave and is provided in the shape of an arc being the segment of a circle O;
a transport layer being affixed to the second surface of the light transmitting body; and
a light collection port embedded within the transport layer;
wherein each of the reflective bodies are defined as having a constrained area between the arc, the arc being defines as a line A₀-A_{X}, a first line A₀-B about a back surface and a bottom surface being defined as a second line B-C, wherein an end of the second line B-C, is provided along the line A₀-A_{X}; and
wherein light (a) enters into the light-transmitting body incidentally so as to enter the circle O, wherein a point A is defined as a point on the circle O where the light a enters the light-transmitting body, wherein a line O-A is a horizontal radial line with respect to the circle O, wherein the light (a) and the circle O intersect on the reflective surface of each of the reflective bodies at a point A₀, wherein the angle between the line A-O and the point A₀ is defined as α, wherein the intersection between a point A₁ is defined by a second reflection point and with the primary reflection line A₀-A₁ has an angle being 3 times that of a, and wherein the intersection of a point A₂ being defined as a third reflection point and wherein the angle of a secondary reflection line A₁-A₂ and the arc has an angle <AO-A₂ being equal to 5 times α.

18. The solar energy collection and transmission system according to claim 17, wherein each of the reflective bodies are configured to reflect incoming light a plurality of times, and wherein an angle between the line A-O and an ultimate reflection point can be described by the equation <A-O-An=(2n+1)α, wherein n is the number of times the light is reflected on the reflective surface of each reflective body.

19. The solar energy collection and transmission system according to claim 17, further comprising:
a first reflective film surrounding each of the reflective bodies;
a second reflective film provided on a top surface of the transport layer and between the second transmissive film and an upper surface of the transport layer the second reflective film facing into the transport layer.

20. The solar energy collection and transmission system according to claim 19, further comprising:
a third reflective film provided on a bottom surface of the transport layer and facing into the transport layer.
